(19) United States
(12) Patent Application Publication
(10) Pub. No.: US 2026/0052932 A1
(43) Pub. Date: Feb. 19, 2026

(54) HEAT EXCHANGE MODULE AND SUBSTRATE PROCESSING APPARATUS INCLUDING THE SAME

(71) Applicant: WONIK IPS CO., LTD., Pyeongtaek-si (KR)

(72) Inventors: Jeong Lim SON, Pyeongtaek-si (KR); Joo Suop KIM, Pyeongtaek-si (KR); Kee Jun KIM, Pyeongtaek-si (KR); Sang Cheol PARK, Pyeongtaek-si (KR); Jae Hwan LIM, Pyeongtaek-si (KR)

(21) Appl. No.: 19/266,543

(22) Filed: Jul. 11, 2025

(30) Foreign Application Priority Data
Aug. 16, 2024 (KR) 10-2024-0109906

(51) Int. Cl. H01L 21/67; F27B 17/00; F27D 9/00

(52) U.S. Cl. CPC H01L 21/67109; F27B 17/0025; F27D 2009/0005

(57) ABSTRACT

A heat exchange module installed to be in constant communication with a high-pressure vessel forming a heating space (S2) under high-temperature and high-pressure process conditions, comprises: a main body unit (500) forming a heat exchange space (S4) therein; a flow path forming unit (600) provided to form a flow path in which exhaust gas discharged from the high-pressure vessel flows within the heat exchange space (S4); and a heat medium piping unit (700), at least a portion of which is installed within the heat exchange space (S4), with a heat medium flowing therein for direct or indirect heat exchange with the exhaust gas.

### CROSS-REFERENCE TO RELATED APPLICATIONS

This U.S. non-provisional patent application claims priority under 35 U.S.C. § 119 of Korean Patent Application No. 10-2024-0109906, filed on Aug. 16, 2024, the entire contents of which are hereby incorporated by reference.

### FIELD OF THE INVENTION

The present invention relates to a heat exchange module and a substrate processing apparatus including the same, and more particularly, to a high-pressure heat exchange module and a substrate processing apparatus including the same.

### BACKGROUND ART

A substrate processing apparatus is an apparatus that processes a substrate such as a wafer, and a reactor using a boat may be used to perform processes such as deposition, etching, and heat treatment on a plurality of substrates.

In such a conventional reactor-type substrate processing apparatus, a single or double tube, into which a plurality of substrates are inserted by a boat to perform substrate processing, is applied, and a heater is provided at the outermost part to supply heat to form a process temperature atmosphere.

Meanwhile, for various processes on a substrate, particularly for an annealing process that improves film quality through recrystallization of the substrate surface by removing residues remaining on and within the substrate surface, it may be necessary to perform substrate processing by creating a high temperature of 800° C. or more and a high pressure of 2 ATM or more, as required.

However, conventional substrate processing apparatuses applied a double tube for protection in case of tube breakage due to the creation of a high-pressure state of 2 ATM or more. However, in the case of quartz material, there is a problem that its durability is weak due to a high risk of damage under a high-pressure environment, and contamination due to gas leakage may occur in case of damage.

Furthermore, if the material of the double tube is reinforced in response to this, there is a problem that a sufficient high-temperature condition for substrate processing is difficult to achieve, as the heat transfer rate is low due to the material, making it difficult to receive heat from a heater located at the outermost part.

Meanwhile, such a substrate processing apparatus is generally provided with a radiator for cooling the cooling gas, which is supplied and exhausted to cool the heater and surrounding components after a high-temperature process.

However, in conventional substrate processing apparatuses, substrate processing is performed under conditions of 2 ATM or more and 800° C. or more inside, and then, in the process of supplying and exhausting the cooling gas, the temperature of the cooling gas is very high. As a result, the sealing between the radiator and the inside of the tube cannot be maintained due to damage to the sealing member between the radiator and the tube, and the radiator is damaged due to exposure to the high pressure inside the tube.

### SUMMARY OF THE INVENTION

The object of the present invention is to provide a heat exchange module operable under a high-pressure environment and a substrate processing apparatus including the same, in order to solve the above problems.

The present invention has been created to achieve the above object of the present invention, and the present invention discloses a heat exchange module installed to be in constant communication with a high-pressure vessel forming a heating space (S2) under high-temperature and high-pressure process conditions, comprising: a main body unit (500) forming a heat exchange space (S4) therein; a flow path forming unit (600) provided to form a flow path in which exhaust gas discharged from the high-pressure vessel flows within the heat exchange space (S4); and a heat medium piping unit (700), at least a portion of which is installed within the heat exchange space (S4), with a heat medium flowing therein for direct or indirect heat exchange with the exhaust gas.

The heat exchange module may include a reinforcing rib (800) provided on at least a portion of the outer surface of the main body unit (500) to reinforce the main body unit (500) according to the high-pressure state of the heat exchange space (S4).

The main body unit (500) may have a rectangular cross-section including the heat exchange space (S4), and the reinforcing rib (800) may be coupled to an extension part (540) of which end protrudes laterally from the upper surface of the main body unit (500) and extends.

A plurality of the reinforcing ribs (800) may be provided to have a length in a direction that intersects a virtual straight line connecting one end where the exhaust gas flows into the main body unit (500) and the other end where the exhaust gas is discharged, and to be parallel to each other.

A plurality of the reinforcing ribs (800) may be provided to have a length in a planar direction of a virtual straight line connecting one end where the exhaust gas flows into the main body unit (500) and the other end where the exhaust gas is discharged, and to be parallel to each other.

The heat exchange module may include a buffer space forming unit (900) provided on the inner surface of the main body unit (500) to form a buffer space (S5) between the flow path forming unit (600) and the main body unit (500) such that the flow path forming unit (600) is spaced apart from the inner surface of the main body unit (500).

The main body unit (500) may have a rectangular cross-section including the heat exchange space (S4), and the buffer space forming unit (900) may be provided on at least one of the ceiling surface, the bottom surface, and both side surfaces of the main body unit (500).

The main body unit (500) may include a housing (510) forming the heat exchange space (S4), a first flange part (520) provided at one end of the housing (510) for inflow of the exhaust gas, and a second flange part (530) provided at the other end of the housing (510) for outflow of the exhaust gas.

A sensor (8) for measuring the parameters of the exhaust gas discharged from the housing (510) may be installed on the second flange part (530).

The flow path forming unit (600) may include a plurality of flow path forming plates (610) parallel to each other such that a plurality of the flow paths are formed therebetween.

The heat medium piping unit (700) may include a heat exchange pipe unit (710) provided to intersect the flow path formed through the flow path forming unit (600) and having the heat medium flowing therein, and a heat medium transfer unit (720) connected to each end of the heat exchange pipe unit (710) by penetrating the main body unit (500) from outside the main body unit (500) to supply and discharge the heat medium.

The heat medium piping unit (700) may further include a branching heat medium transfer unit (730) branched from the heat medium transfer unit (720) to transfer the heat medium to a heat medium flow path (501) formed in the main body unit (500).

The heat medium flow path (501) may be formed at a position adjacent to the high-pressure vessel in the main body unit (500).

The main body unit (500) may further include a second sealing member (521) provided between itself and the high-pressure vessel, and the heat medium flow path (501) may be formed at a position adjacent to the second sealing member (521) in the main body unit (500).

Further, the present invention discloses a substrate processing apparatus comprising: an inner tube (100) having a processing space (S1) formed therein; a heater unit (200) installed to surround at least a portion of the inner tube (100) and forming a heating space (S2) between itself and the inner tube (100); an outer tube (300) in which the inner tube (100) and the heater unit (200) are disposed, and forming an internal space (S3) between itself and the heater unit (200); and a heat exchange module (90) installed outside the heater unit (200) to be in constant communication with the heating space (S2) and performing heat exchange with exhaust gas discharged from the heating space (S2).

The heat exchange module (90) may be coupled and installed to the outer tube (300) from outside the outer tube (300).

The outer tube (300) may include a vessel part (310) forming the internal space (S3) and having an opening (301) formed on its side; a flange part (320) protruding from the vessel part (310) at a position corresponding to the opening (301); and an opening/closing door part (330) installed on the flange part (320) to open and close the opening (301), and having a door opening (331) formed therethrough.

The heat exchange module (90) may be installed on the opening/closing door part (330) by covering the door opening (331) so as to communicate with the heating space (S2) through the door opening (331).

The substrate processing apparatus may further include a damper unit (400) installed between the heater unit (200) and the heat exchange module (90) to communicate the heating space (S2) and the heat exchange module (90).

The heater unit (200) may include a side insulation part (210) disposed to surround the inner tube (100); a heating part (220) provided on the inner surface of the side insulation part (210) to generate heat according to applied power; and an upper insulation part (230) provided on the upper end of the side insulation part (210), having an exhaust flow path (231) formed therein for discharging exhaust gas from the heating space (S2), and coupled to the damper unit (400).

The heating space (S2) and the internal space (S3) may be in communication with each other.

The inner tube (100) may include quartz, and the outer tube (300) may include SUS.

The internal space (S3) may be maintained at a higher pressure than the processing space (S1).

The heating space (S2) may maintain a temperature of 800° C. or more during at least a portion of the process performed in the processing space (S1).

The internal space (S3) may maintain a pressure of 2 ATM or more during at least a portion of the process performed in the processing space (S1).

The heat exchange module and the substrate processing apparatus including the same according to the present invention have the advantage that the protection function is improved as an outer tube that can be used without damage even at a high pressure of 2 ATM or more is applied to the outermost part, and heating efficiency is increased through the proximity of the heater unit to the inner tube.

Further, the heat exchange module and the substrate processing apparatus including the same according to the present invention have the advantage that high-pressure process can be performed even in a state of constant communication with the heat exchange module, as a heat exchange module with reinforced rigidity to prevent damage due to high-pressure exposure is applied.

Further, the heat exchange module and the substrate processing apparatus including the same according to the present invention have the advantage that stable heat exchange and function implementation are possible even with frequent exposure to high-pressure and high-temperature process environments through the pressure-resistant design of the heat exchange module.

### BRIEF DESCRIPTION OF THE DRAWINGS

FIG. 1 is a perspective view showing a substrate processing apparatus according to the present invention.

FIG. 2 is a cross-sectional view showing the substrate processing apparatus according to FIG. 1.

FIG. 3 is an enlarged cross-sectional view showing the connection part of the heat exchange module in the substrate processing apparatus according to FIG. 2.

FIG. 4 is a perspective view showing the appearance of a heat exchange module according to the present invention.

FIG. 5 is a bottom perspective view showing the appearance of the heat exchange module according to FIG. 4.

FIG. 6 is a planar cross-sectional view showing a cross-section of the heat exchange module according to FIG. 4 viewed from the A-A′ direction.

FIG. 7 is a cross-sectional view showing a cross-section of the heat exchange module according to FIG. 4 in the B-B′ direction.

FIG. 8 is a bottom perspective view showing the appearance of the heat exchange part outside the main body unit in the heat exchange module according to FIG. 4.

### DETAILED DESCRIPTION OF THE PREFERRED EMBODIMENTS

Hereinafter, the heat exchange module and the substrate processing apparatus including the same according to the present invention will be described in detail with reference to the accompanying drawings.

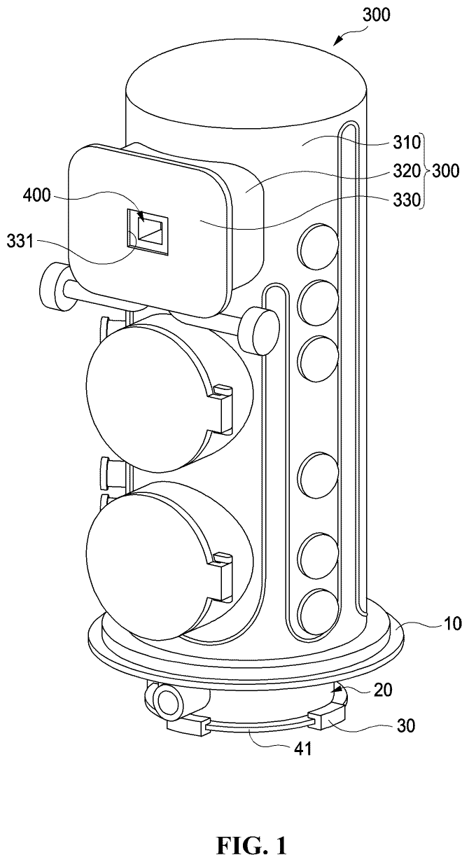

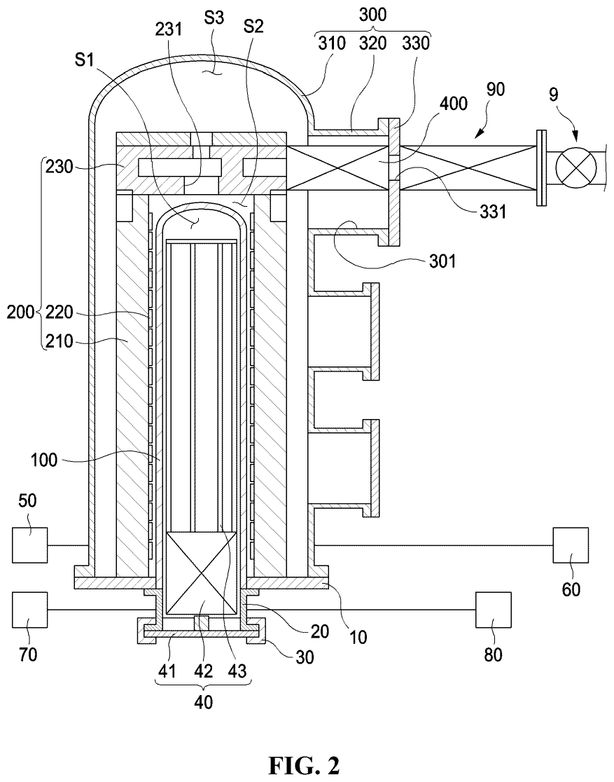

As shown in FIGS. 1 and 2, the substrate processing apparatus according to the present invention includes: an inner tube (100) having a processing space (S1) formed therein; a heater unit (200) installed to surround at least a portion of the inner tube (100) and forming a heating space (S2) between itself and the inner tube (100); an outer tube (300) in which the inner tube (100) and the heater unit (200) are disposed, and forming an internal space (S3) between itself and the heater unit (200); and a heat exchange module (90) installed outside the heater unit (200) to be in constant communication with the heating space (S2) and performing heat exchange with exhaust gas discharged from the heating space (S2).

Further, the substrate processing apparatus according to the present invention may further include a damper unit (400) installed between the heater unit (200) and the heat exchange module (90) to communicate the heating space (S2) and the heat exchange module (90).

Here, the substrate to be processed can be understood to include all substrates, such as those used in display devices like LEDs, LCDs, OLEDs, semiconductor substrates, solar cell substrates, and glass substrates.

Further, any conventionally disclosed process can be applied as the process performed by the substrate processing apparatus according to the present invention, as long as it is a process for treating a substrate. For example, processes such as deposition, etching, and heat treatment can be performed.

For example, the substrate processing apparatus according to the present invention can perform annealing to improve the film quality of a substrate such as a wafer, and in particular, it can effectively improve film quality by promoting recrystallization or migration of the substrate surface through effective removal of impurities remaining on or weakly bonded to the surface and interior of the substrate or thin film.

In this case, the substrate processing apparatus according to the present invention can repeatedly perform a high-pressure process, for example, a high pressure of 2 ATM or more, which is higher than atmospheric pressure, in the processing space (S1) where substrate processing is performed, and a low-pressure process in a vacuum state. If necessary, heat treatment at a high temperature of 800° C. or more can be performed.

The inner tube (100) is a component that forms a processing space (S1) therein, and various configurations are possible.

In this case, the inner tube (100) may be a vertical cylindrical shape with a dome-shaped ceiling, forming a processing space (S1) therein, with its lower part open so that a boat (40) loaded with a plurality of substrates, described later, can be loaded and unloaded.

That is, the inner tube (100) has its lower part open, allowing a boat (40) loaded with a plurality of substrates to be inserted through the lower part, thereby forming a sealed processing space (S1) where substrate processing can be performed. After the substrate processing is completed, the boat (40) can be lowered and processed substrates may be unloaded and new substrates to be processed may be loaded to the boat (40).

In this case, the boat (40) may include a support part (43) that supports a plurality of substrates spaced apart vertically, an insulation part (42) provided below the support part (43) to prevent heat loss from the processing space (S1) to the outside, and a cap flange (41) below the insulation part (42) that supports the insulation part (42) and the substrate support part (43).

Accordingly, when the boat (40) is raised and loaded into the processing space (S1) within the inner tube (100), the cap flange (41) can be in close contact with the lower end of the manifold (20), and they can be coupled to each other through a clamp (30) that clamps the edges of the cap flange (41) and the lower end of the manifold (20) to form a sealed processing space (S1).

In particular, the clamp (30), by clamping and fixing the manifold (20) and the cap flange (41), prevents the cap flange (41) from moving downward due to the internal high pressure when a high-pressure process of 2 ATM or more is performed in the processing space (S1), and can maintain the sealed state of the processing space (S1).

Meanwhile, the inner tube (100) may be supported by a manifold (20) installed at its open lower end and communicate with the manifold (20). In this case, process gas can be received from an external first gas supply unit (80) through a supply port formed in the manifold (20).

Furthermore, the inner tube (100) may have process gas discharged to the external first gas exhaust unit (80) through an exhaust port formed in the manifold (20), thereby exhausting the processing space (S1).

The inner tube (100) is a non-metallic material, which may be made of quartz, and as described above, it may have a dome-shaped ceiling, but it is not limited thereto, and it may also be configured in a cylindrical shape with a flat ceiling.

The heater unit (200) may be configured to surround at least a portion of the inner tube (100) and form a heating space (S2) between itself and the inner tube (100).

That is, the heater unit (200) may be configured to have the inner tube (100) disposed inside it, forming a heating space (S2) between itself and the inner tube (100), and heating it to form the interior of the processing space (S1) into a process temperature atmosphere.

To this end, the heater unit (200) may include a side insulation part (210) disposed to surround the inner tube (100); a heating part (220) provided on the inner surface of the side insulation part (210) to generate heat according to applied power; and an upper insulation part (230) provided on the upper end of the side insulation part (210), having an exhaust flow path (231) formed therein for discharging exhaust gas from the heating space (S2), and coupled to the damper unit (400).

The side insulation part (210) is a component disposed to surround the inner tube (100) and may form the side surface of the heater unit (200).

In this case, the side insulation part (210) may be configured to form its side surface through a plurality of insulating materials, and the heating part (220) may be disposed on its inner surface to concentrate heat into the heating space (S2) and the processing space (S1) and minimize heat loss to the outside of the side insulation part (210).

Further, the side insulation part (210) may be formed by stacking a plurality of annular members, and in this case, a plurality of gas supply ports (not shown) may be formed to penetrate radially between or in the annular members, so that the internal space (S3) and the heating space (S2) communicate with each other, and cooling gas supplied from outside can be guided to be transferred into the heating space (S2).

The heating part (220) is a component provided on the inner surface of the side insulation part (210) to generate heat according to applied power, and various configurations are possible.

In this case, the heating part (220) is a component that generates heat through resistance heat generated by a resistor to which electric power is applied, and the amount of heat generation and temperature can be adjusted by appropriately controlling the applied power.

Meanwhile, the heating part (220) may be provided in a plurality of units in the vertical direction on the inner surface of the side insulation part (210), and its ends may penetrate the side insulation part (210) to receive power from the outside through terminal parts provided outside the side insulation part (210).

The upper insulation part (230) may be configured to be provided on the upper end of the side insulation part (210) and have an exhaust flow path (231) formed therein for discharging exhaust gas from the heating space (S2).

That is, the upper insulation part (230) is a component that forms the upper end and ceiling of the heater unit (200), and by being provided on the upper end of the side insulation part (210) including a plurality of insulation plates, it can prevent heat loss upwards from the heating space (S2).

Meanwhile, the upper insulation part (230) may have an exhaust flow path (231) formed for the external discharge of cooling gas supplied to the heating space (S2). For example, the exhaust flow path (231) may be formed to extend from an exhaust port formed on the bottom surface of the upper insulation part (230), i.e., the ceiling surface of the heater unit (200), to the side surface of the upper insulation part (230), thereby guiding the exhaust gas, which is the cooling gas that has completed heat exchange, to be discharged to the outside.

In this case, the upper insulation part (230) may have a damper unit (400), described later, coupled to its side so as to communicate with the exhaust flow path (231). This can guide the exhaust gas, which is cooling gas supplied to the heating space (S2) and has performed heat exchange, to be transferred to the damper unit (400) through the exhaust flow path (231).

The outer tube (300) is a component in which the inner tube (100) and the heater unit (200) are disposed, and forms an internal space (S3) between itself and the heater unit (200). Various configurations are possible.

That is, the outer tube (300) is a component installed to surround the heater unit (200), which can form an internal space (S3) between itself and the heater unit (200), and can be a vertical cylindrical structure with a dome-shaped ceiling, corresponding to the aforementioned inner tube (100).

Meanwhile, the outer tube (300) may be disposed outside the inner tube (100), where high-temperature and high-pressure substrate processing is performed, and the heater unit (200), which surrounds the inner tube (100), thereby forming an internal space (S3) as a protective space. Accordingly, it can be configured to prevent external leakage of process gas due to damage to the inner tube (100) during high-pressure substrate processing and to have sufficient rigidity against high pressure.

To this end, the outer tube (300) may be made of a metal material, and for example, may include SUS.

Meanwhile, the internal space (S3) formed between the outer tube (300) and the heater unit (200) can be maintained at a higher pressure than the processing space (S1) to act as a protective space, as described above. Since the heater unit (200) is not sealed and allows gas to pass through, it can communicate with the heating space (S2).

That is, the internal space (S3) can be maintained at a pressure of 2 ATM or more during at least a portion of the process performed in the processing space (S1), and when the heating space (S2) is maintained at a temperature of 800° C. or more during at least a portion of the process performed in the processing space (S1) due to the heating of the heating space (S2), it can be maintained at a similar temperature.

Meanwhile, the outer tube (300) has separate supply ports and exhaust ports formed on its side, and each is connected to a second gas supply unit (60) and a second gas exhaust unit (50) to receive gas into the internal space (S3) from outside and to exhaust the internal space (S3).

Further, the heater unit (200) and the outer tube (300) are each configured with an open lower end, and their open lower ends can be supported and installed on a base unit (10). In this case, the aforementioned manifold (20) can be coupled and installed on the bottom surface of the base unit (10).

For example, the outer tube (300) may include a vessel part (310) that forms the internal space (S3) and has an opening (301) formed on its side; a flange part (320) protruding from the vessel part (310) at a position corresponding to the opening (301); and an opening/closing door part (330) installed on the flange part (320) to open and close the opening (301), and having a door opening (331) formed therethrough.

The vessel part (310) is a component that forms the internal space (S3) and has an opening (301) formed on its side, and various configurations are possible.

For example, the vessel part (310) may be made of SUS material and have a dome-shaped ceiling, and may be provided such that the heater unit (200) and the inner tube (100) are inserted therein. Its lower end may be open and supported and installed on the base unit (100).

In this case, the vessel part (310) may have an opening (301) formed on its side, which allows access for maintenance of the damper unit (400) installed in the internal space (S3) for external discharge of cooling gas supplied to the heating space (S2).

The flange part (320) may be formed as a component protruding from the vessel part (310) at a position corresponding to the opening (301), and the opening/closing door part (330) may be installed to open and close the opening (301).

In this case, the opening/closing door part (330) may be configured to be coupled to and separable from the flange part (320) with a first sealing member (332) interposed therebetween, thereby closing and opening the opening (301).

Meanwhile, the opening/closing door part (330) may be coupled to the flange part (320) via bolting with a first sealing member (332) interposed therebetween. A hinge part may be provided at one end, allowing the opening (301) to be opened by hinge rotation after the bolts are loosened.

Furthermore, the opening/closing door part (330) may further include a door opening (331) formed therethrough to allow communication between a damper unit (400), described later, and an external heat exchange module (90).

That is, with the door opening (331) formed therethrough, the opening/closing door part (330) can have the damper unit (400) coupled to its inner surface to cover the door opening (331), and the heat exchange module (90) coupled to its outer surface to cover the door opening (331), thereby allowing communication between the damper unit (400) and the heat exchange module (90).

Further, the opening/closing door part (330) and the flange part (320) where the opening/closing door part (330) is installed may be formed in a rectangular shape in front view, corresponding to the damper unit (400) described later.

The damper unit (400) is a component installed between the heater unit (200) and the heat exchange module (90) to communicate the heating space (S2) and the heat exchange module (90). Various configurations are possible.

For example, at least a portion of the damper unit (400) may be disposed within the flange part (320). One end may be coupled to the heater unit (200), and the other end may be coupled to the opening/closing door part (330) by covering the door opening (331) so as to communicate with the heat exchange module (90).

That is, the damper unit (400) has an end opening (401) formed at the end in the direction of the opening/closing door part (330), and is disposed to cover the door opening (331), thereby forming a flow path for exhaust gas in the order of the damper unit (400), the door opening (331) of the opening/closing door part (330), and the heat exchange module (90).

In this case, the end opening (401) may be the same size as the door opening (331), or as another example, it may be larger or smaller than the door opening (331).

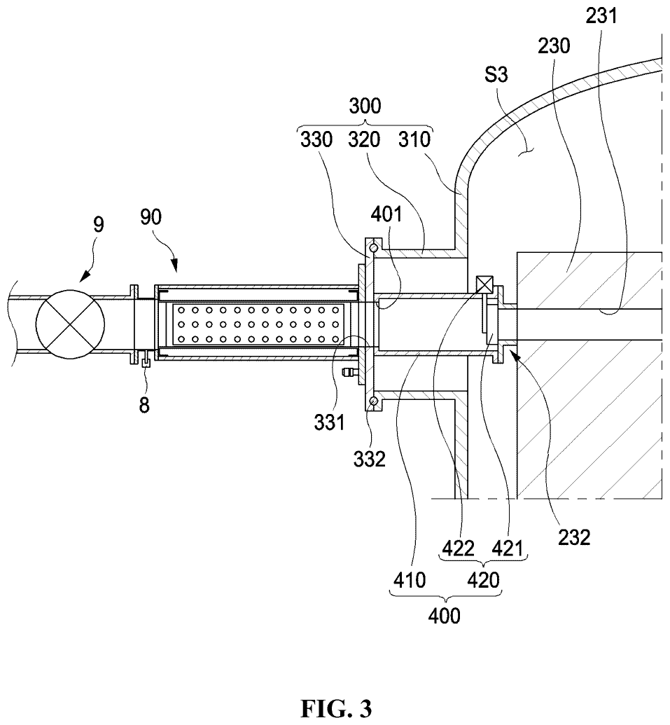

For example, as shown in FIG. 3, the damper unit (400) may include a damper body (410) having a flow path for exhaust gas formed therein, and a flow rate adjusting unit (420) provided within the damper body (410) to adjust the degree of opening of the flow path.

More specifically, the damper unit (400) may have a damper body (410), in which a flow path for exhaust gas discharged through the exhaust flow path (231) is formed. One end of the damper body (410) may be coupled to an exhaust flow path flange (232) formed on the side wall of the upper insulation part (230) so as to communicate with the exhaust flow path (231), and the other end may be coupled to the opening/closing door part (330).

In this case, the damper unit (400), as a flow rate adjusting unit (420), may include a driving unit (422) that generates power, such as a motor or actuator, to drive a blade (421), and a blade (421) that controls the exhaust gas flow in the flow path through the driving unit (422), thereby appropriately adjusting the flow rate of exhaust gas discharged through the damper unit (400).

Meanwhile, the damper unit (400) may be configured to be openable and closable, but it may not be completely shut off and may be in constant communication with the exhaust flow path (231) and the heat exchange module (90) described later. Accordingly, since it is in constant communication with the heating space (S2) and the internal space (S3) communicating with the heating space (S2), the interior can be maintained at high pressure, and high-temperature exhaust gas can be transferred.

That is, the damper unit (400) is a component that transfers high-temperature and high-pressure exhaust gas. Although it is difficult to maintain a sealed state with the heat exchange module (90) described later through a sealing member, and therefore, it can maintain a constant communication state with the heating space (S2) and the heat exchange module (90) without maintaining a complete sealed state.

The heat exchange module (90) is installed outside the heater unit (200) to be in constant communication with the heating space (S2), and performs heat exchange with exhaust gas discharged from the heating space (S2). Various configurations are possible.

More specifically, the heat exchange module (90) may be a radiator configuration that performs heat exchange to cool high-temperature exhaust gas. After substrate processing due to heating by the heater unit (200), cooling gas is supplied to the heating space (S2) through the outer tube (300) for rapid cooling of the heating space (S2), inner tube (100), etc. At this time, the supplied cooling gas performs heat exchange in the heating space (S2) and is then discharged through the exhaust flow path (231).

In particular, as described above, the heat exchange module (90) must cool and discharge high-temperature and high-pressure exhaust gas to the outside. Therefore, it is impossible to apply a sealing member due to the high-temperature and high-pressure atmosphere, making it difficult to maintain a complete seal with the aforementioned damper unit (400) and internal space (S3). Accordingly, it can be applied in a structure that is in constant communication with the heating space (S2).

To this end, the heat exchange module (90) can be coupled and installed to the outer tube (300) from outside the outer tube (300) to cool and discharge exhaust gas to the outside.

For example, the heat exchange module (90) may be installed on the opening/closing door part (330) by covering the door opening (331) so as to communicate with the heating space (S2) through the door opening (331). This allows it to be directly connected to and communicate with the aforementioned damper unit (400).

Meanwhile, the heat exchange module (90), due to constant communication with the heating space (S2) described above, may have high pressure formed inside during substrate processing in the processing space (S1), and high-temperature exhaust gas may be transferred after substrate processing is completed.

Accordingly, a configuration with reinforced rigidity can be applied to enable stable heat exchange and discharge of exhaust gas to the outside without deformation even under high-pressure conditions.

Hereinafter, the heat exchange module according to the present invention will be described in detail with reference to the accompanying drawings.

As shown in FIG. 3, the heat exchange module according to the present invention includes: a main body unit (500) forming a heat exchange space (S4) therein; a flow path forming unit (600) provided to form a flow path in which exhaust gas discharged from the high-pressure vessel flows within the heat exchange space (S4); and a heat medium piping unit (700), at least a portion of which is installed within the heat exchange space (S4), with a heat medium flowing therein for direct or indirect heat exchange with the exhaust gas.

In this case, the heat exchange module according to the present invention is installed to communicate with a high-pressure vessel forming a heating space (S2) under high-temperature and high-pressure process conditions. Here, the high-pressure vessel may be a configuration corresponding to the aforementioned outer tube (300).

Further, the heat exchange module according to the present invention may include a reinforcing rib (800) provided on at least a portion of the outer surface of the main body unit (500) to reinforce the main body unit (500) according to the high-pressure state of the heat exchange space (S4).

Further, the heat exchange module according to the present invention may include a buffer space forming unit (900) provided on the inner surface of the main body unit (500) to form a buffer space (S5) between the flow path forming unit (600) and the main body unit (500) such that the flow path forming unit (600) is spaced apart from the inner surface of the main body unit (500).

The main body unit (500) is a component that forms a heat exchange space (S4) therein, and various configurations are possible.

For example, the main body unit (500) may include a housing (510) forming the heat exchange space (S4), a first flange part (520) provided at one end of the housing (510) for inflow of the exhaust gas, and a second flange part (530) provided at the other end of the housing (510) for outflow of the exhaust gas.

In this case, the housing (510) is a component that forms a heat exchange space (S4) therein, and corresponding to the aforementioned damper unit (400) and opening/closing door part (330), its longitudinal cross-section including the heat exchange space (S4) may be a hexahedron having a rectangular cross-section.

Meanwhile, the housing (510) may include an extension part (540) of which upper surface extends laterally for the installation of a reinforcing rib (800), described later. In this case, the extension part (540) may be formed to extend in both lateral directions crossing the exhaust gas flow path from the upper surface of the housing (510), or may be separately coupled and installed to protrude in both lateral directions on the upper surface (510).

The first flange part (520) is a component provided at one end of the housing (510) for inflow of exhaust gas, and may be configured to be coupled to the opening/closing door part (330) to cover the door opening (331).

In this case, the first flange part (520) comes into contact along the door opening (331) of the opening/closing door part (330), and a second sealing member (521) may be disposed therebetween.

Further, the first flange part (520) can be bolted to the bottom surface of the opening/closing door part (330), and a heat medium flow path (501) is formed inside to allow the heat medium to flow, thereby appropriately adjusting the temperature rise due to the inflow of high-temperature exhaust gas.

In particular, the heat medium flow path (501) of the first flange part (520) is formed at a position adjacent to the second sealing member (521), which is in contact with the door opening (331) of the opening/closing door part (330) and provided therebetween. This lowers the temperature at the position adjacent to the second sealing member (521), preventing the second sealing member (521) from deteriorating or being damaged by the temperature rise due to the inflow of high-temperature exhaust gas, and reinforcing the durability of the second sealing member (521).

The second flange part (530) may be configured to have a sensor (8) installed therein for measuring parameters of exhaust gas discharged from the housing (510).

The second flange part (530) can be coupled to an exhaust pipe provided with a valve (9) to transfer the exhaust gas, which has completed heat exchange and been cooled, to the exhaust pipe side.

In this case, a sensor (8) for measuring the temperature of the discharged exhaust gas is provided to measure the temperature of the exhaust gas and appropriately control the heat medium piping unit (700) accordingly.

The flow path forming unit (600) is a component provided to form a flow path in which exhaust gas discharged from the high-pressure vessel flows within the heat exchange space (S4), and various configurations are possible.

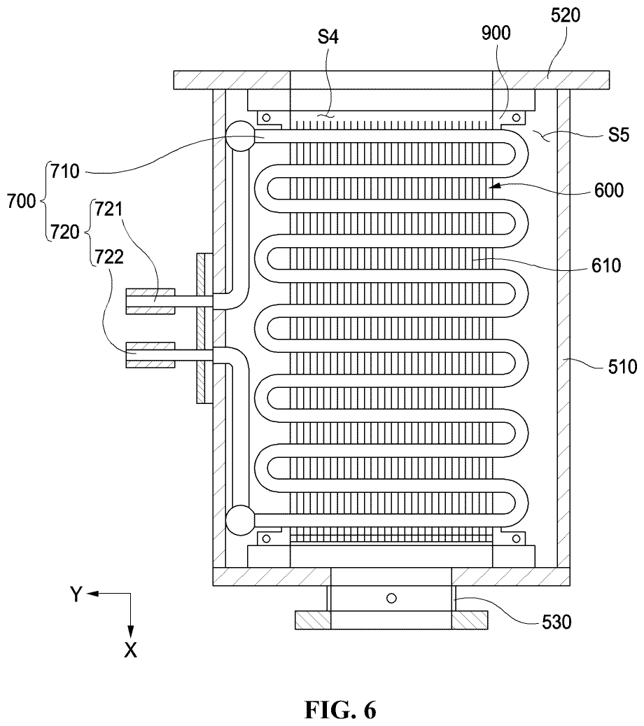

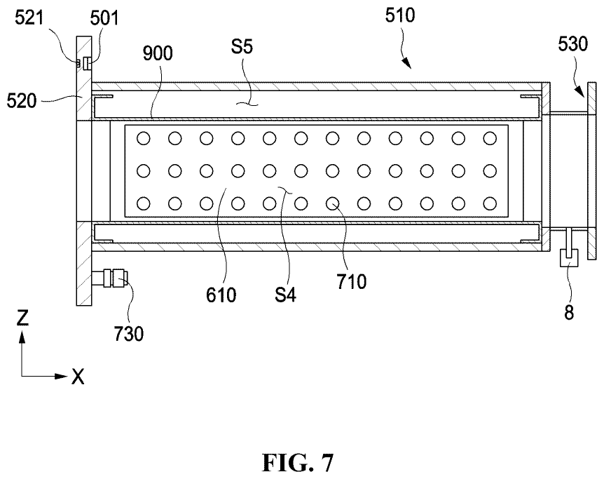

For example, as shown in FIGS. 6 and 7, the flow path forming unit (600) may have a plurality of flow path forming plates (610) parallel to each other such that a plurality of flow paths are formed therebetween, thereby allowing exhaust gas introduced through the first flange part (520) to flow. In this process, the heat medium piping unit (700), described later, can be disposed in the flow path to induce heat exchange between the exhaust gas and the heat medium piping unit (700) through contact.

Meanwhile, the flow path forming unit (600) may be provided with a fixing part (not shown) disposed at an end to fix a plurality of flow path forming plates (610), and may be formed spaced apart from the inner surface of the housing (510) through a buffer space forming unit (900) described later.

Further, unlike the aforementioned description, the flow path forming unit (600) may be provided with a plurality of plates parallel to each other and perpendicular to the direction of exhaust gas flow, and a plurality of flow path forming holes may be provided in these plates to form flow paths for exhaust gas. In this case, the flow path forming holes between adjacent plates may be aligned, or may be arranged to be misaligned to increase the heat exchange time and area of the exhaust gas.

Furthermore, unlike the aforementioned description, the flow path forming unit (600) may be provided as a connecting pipe connecting the inlet side, where exhaust gas flows into the main body unit (500), and the outlet side, where exhaust gas is discharged from the main body unit (500). In short, various conventionally disclosed flow path forming structures for inducing the movement of exhaust gas within the main body unit (500) can be applied without limitation.

The heat medium piping unit (700) is a component, at least a portion of which is installed within the heat exchange space (S4), and through which a heat medium flows for direct or indirect heat exchange with the exhaust gas. Various configurations are possible.

For example, the heat medium piping unit (700) may be configured to be disposed in contact with the exhaust gas in the flow path formed by the flow path forming unit (600), and to induce cooling through heat exchange with the flowing high-temperature exhaust gas by having a heat medium flowing therein.

For example, the heat medium piping unit (700) may include a heat exchange pipe unit (710) provided to intersect the flow path formed through the flow path forming unit (600) and having the heat medium flowing therein, and a heat medium transfer unit (720) connected to each end of the heat exchange pipe unit (710) by penetrating the main body unit (500) from outside the main body unit (500) to supply and discharge the heat medium.

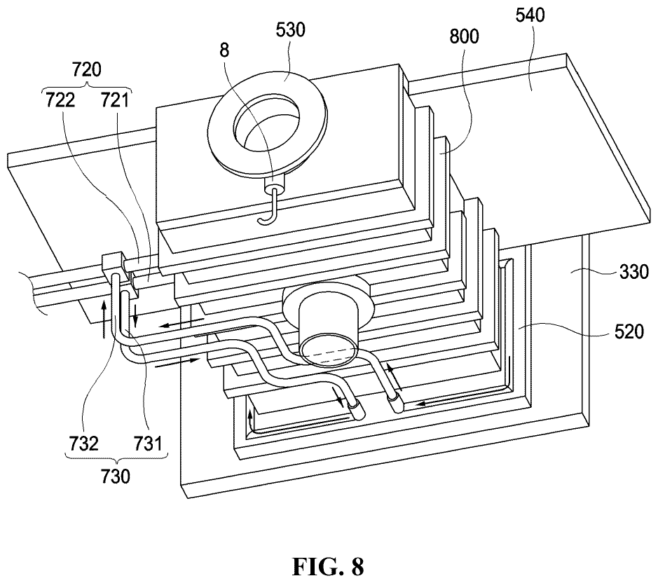

Further, as shown in FIG. 8, the heat medium piping unit (700) may further include a branching heat medium transfer unit (730) branched from the heat medium transfer unit (720) to transfer the heat medium to a heat medium flow path (501) formed in the main body unit (500).

The heat exchange pipe unit (710) is a component in which a heat medium flows, and may be installed in the flow path forming unit (600) so as to intersect the flow path formed through the flow path forming unit (600).

In this case, the heat exchange pipe unit (710) may be disposed by penetrating the flow path forming plate (610) in a direction crossing the longitudinal direction of the flow path, and may be repeatedly formed by a combination of straight lines and curves to increase the contact time and contact area with the exhaust gas.

The heat medium transfer unit (720) is a component that supplies and discharges the heat medium by penetrating the main body unit (500) from outside the main body unit (500) and connecting to each end of the heat exchange pipe unit (710). It may include a heat medium supply unit (721) that receives heat medium from outside and transfers it to one end of the heat exchange pipe unit (710), and a heat medium recovery unit (722) that receives the heat medium that has completed heat exchange from the other end of the heat exchange pipe unit (710) and transfers it to outside.

In this case, the heat medium transfer unit (720) may be provided to penetrate the side wall of the housing (510) while maintaining a sealed state, and may be connected to the heat exchange pipe unit (710).

The branching heat medium transfer unit (730) is a component that branches from the heat medium transfer unit (720) and transfers the heat medium to the heat medium flow path (501) formed in the main body unit (500). Various configurations are possible.

For example, the branching heat medium transfer unit (730) may include a branching heat medium supply unit (731) branched from the heat medium supply unit (721) side to transfer the heat medium to one end of the heat medium flow path (501) formed in the aforementioned first flange part (520), and a branching heat medium recovery unit (732) branched from the heat medium recovery unit (721) side to recover the heat medium that has completed heat exchange from the other end of the aforementioned heat medium flow path (501).

In this case, the branching heat medium supply unit (731) and the branching heat medium recovery unit (732) may each include a branch pipe provided to be branched to the heat medium transfer unit (720), and a branch pipe port connecting the branch pipe and the first flange part (520).

Meanwhile, as described above, the heat medium piping unit (700) may be configured to directly contact the exhaust gas to induce heat exchange between the exhaust gas and the heat medium. As another example, it may also be configured to indirectly induce heat exchange between the heat medium and the exhaust gas through a separate medium.

For example, the heat medium piping unit (700) may induce heat exchange between the flow path forming unit (600) and the heat medium by contacting the flow path forming plates (610) at both ends, where the ends of the plurality of flow path forming plates (610) of the flow path forming unit (600) are in contact with each other in a heat-conductive state, and may also induce heat exchange between the flow path forming unit (600) and the exhaust gas.

Further, the heat medium piping unit (700) may also be configured to lower the overall temperature within the heat exchange space (S4), with at least a portion, for example, the heat exchange pipe unit (710), disposed in the heat exchange space (S4), thereby inducing cooling of the exhaust gas through heat exchange with the exhaust gas.

The reinforcing rib (800) is a component provided on at least a portion of the outer surface of the main body unit (500) to reinforce the main body unit (500) according to the high-pressure state of the heat exchange space (S4), and various configurations are possible.

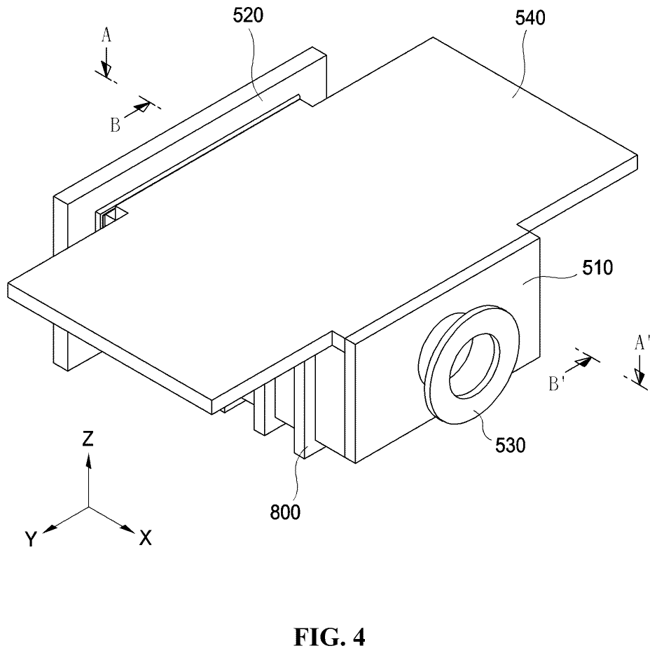

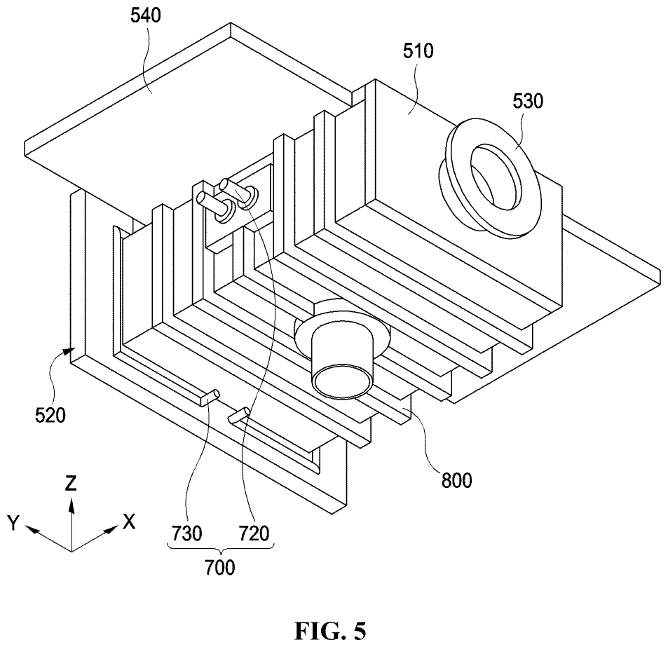

For example, as shown in FIGS. 4 and 5, a plurality of the reinforcing ribs (800) may be provided to have a length in a direction that intersects a virtual straight line connecting one end where the exhaust gas flows into the main body unit (500) and the other end where the exhaust gas is discharged, and to be parallel to each other. More preferably, they may be provided on both side surfaces and the bottom surface of the housing (510) to have a length perpendicular to the virtual straight line in the plane.

In this case, to reinforce rigidity, the end of the reinforcing rib (800) can be coupled to an extension part (540) that protrudes laterally from the upper surface of the main body unit (500) and extends. By coupling the end to the bottom surface of the extension part (540), additional rigidity reinforcement can be maintained through the fixing force with the extension part (540).

Meanwhile, as another example, a plurality of the reinforcing ribs (800) may be provided to have a length in the planar direction of a virtual straight line connecting one end where the exhaust gas flows into the main body unit (500) and the other end where the exhaust gas is discharged, and to be parallel to each other. Accordingly, they may be installed on the bottom surface and parts of both end portions of the housing (510).

The buffer space forming unit (900) is a component provided on the inner surface of the main body unit (500) to form a buffer space (S5) between the flow path forming unit (600) and the main body unit (500) such that the flow path forming unit (600) is spaced apart from the inner surface of the main body unit (500). Various configurations are possible.

In this case, the buffer space forming unit (900) may be provided on at least one of the ceiling surface, the bottom surface, and both side surfaces of the hexahedral housing (510). More preferably, it may be provided on the ceiling surface, the bottom surface, and both side surfaces to induce the flow path forming unit (600) to be spaced apart from the inner surface of the housing (510).

Accordingly, the buffer space forming unit (900) forms a partial buffer space (S5) inside the housing (510), which is maintained at a high-pressure state due to constant communication with the heating space (S2). This prevents direct pressure increase on the wall surface of the housing (510), thereby reinforcing rigidity.

Meanwhile, in this case, the buffer space forming unit (900) may be configured such that the buffer space (S5) communicates with the flow path forming unit (600). As another example, it may be separated from the flow path forming unit (600) and applied as an independent space.

Further, the buffer space forming unit (900) may consist of brackets installed on the inner surface of the housing (510) and frame or plate spaced apart from the inner surface of the housing (510) on the brackets, thereby forming a buffer space (S5) between itself and the inner surface of the housing (510).

The foregoing is merely a description of some of the preferred embodiments that can be implemented by the present invention. As is well known, the scope of the present invention should not be construed as being limited to the above embodiments, and it is understood that all technical ideas that share the technical spirit and fundamental principles of the present invention described above are included within the scope of the present invention.

What is claimed is:

1. A heat exchange module installed to be in constant communication with a high-pressure vessel forming a heating space (S2) under high-temperature and high-pressure process conditions, comprising:
a main body unit forming a heat exchange space therein;
a flow path forming unit provided to form a flow path in which exhaust gas discharged from the high-pressure vessel flows within the heat exchange space; and
a heat medium piping unit, at least a portion of which is installed within the heat exchange space, with a heat medium flowing therein for direct or indirect heat exchange with the exhaust gas.

2. The heat exchange module according to claim 1, further comprising:
a reinforcing rib provided on at least a portion of the outer surface of the main body unit to reinforce the main body unit according to the high-pressure state of the heat exchange space.

3. The heat exchange module according to claim 2, wherein:
the main body unit has a rectangular cross-section including the heat exchange space; and
the reinforcing rib is coupled to an extension part of which end protrudes laterally from the upper surface of the main body unit and extends.

4. The heat exchange module according to claim 2, wherein:
a plurality of the reinforcing ribs are provided to have a length in a direction that intersects a virtual straight line connecting one end where the exhaust gas flows into the main body unit and the other end where the exhaust gas is discharged, and to be parallel to each other.

5. The heat exchange module according to claim 2, wherein:
a plurality of the reinforcing ribs are provided to have a length in a planar direction of a virtual straight line connecting one end where the exhaust gas flows into the main body unit and the other end where the exhaust gas is discharged, and to be parallel to each other.

6. The heat exchange module according to claim 1, further comprising:
a buffer space forming unit provided on the inner surface of the main body unit to form a buffer space between the flow path forming unit and the main body unit such that the flow path forming unit is spaced apart from the inner surface of the main body unit.

7. The heat exchange module according to claim 6, wherein:
the main body unit has a rectangular cross-section including the heat exchange space; and
the buffer space forming unit is provided on at least one of the ceiling surface, the bottom surface, and both side surfaces of the main body unit.

8. The heat exchange module according to claim 1, wherein:
the main body unit comprises:
a housing forming the heat exchange space;
a first flange part provided at one end of the housing for inflow of the exhaust gas; and
a second flange part provided at the other end of the housing for outflow of the exhaust gas.

9. The heat exchange module according to claim 8, wherein:
the second flange part has a sensor installed for measuring the parameters of the exhaust gas discharged from the housing.

10. The heat exchange module according to claim 1, wherein:
the flow path forming unit comprises a plurality of flow path forming plates parallel to each other such that a plurality of the flow paths are formed therebetween.

11. The heat exchange module according to claim 1, wherein:
the heat medium piping unit comprises:
a heat exchange pipe unit provided to intersect the flow path formed through the flow path forming unit and having the heat medium flowing therein; and
a heat medium transfer unit connected to each end of the heat exchange pipe unit by penetrating the main body unit from outside the main body unit to supply and discharge the heat medium.

12. The heat exchange module according to claim 11, wherein:
the heat medium piping unit further comprises a branching heat medium transfer unit branched from the heat medium transfer unit to transfer the heat medium to a heat medium flow path formed in the main body unit.

13. The heat exchange module according to claim 12, wherein:
the heat medium flow path is formed at a position adjacent to the high-pressure vessel in the main body unit.

14. The heat exchange module according to claim 12, wherein:
the main body unit further comprises a second sealing member provided between itself and the high-pressure vessel; and
the heat medium flow path is formed at a position adjacent to the second sealing member in the main body unit.

15. A substrate processing apparatus comprising:
an inner tube having a processing space formed therein;
a heater unit installed to surround at least a portion of the inner tube and forming a heating space between itself and the inner tube;
an outer tube in which the inner tube and the heater unit are disposed, and forming an internal space between itself and the heater unit; and
a heat exchange module installed outside the heater unit to be in constant communication with the heating space and performing heat exchange with exhaust gas discharged from the heating space.

16. The substrate processing apparatus according to claim 15, wherein:
the heat exchange module is coupled and installed to the outer tube from outside the outer tube.

17. The substrate processing apparatus according to claim 15, wherein:
the outer tube comprises:
a vessel part forming the internal space and having an opening formed on its side;
a flange part protruding from the vessel part at a position corresponding to the opening; and
an opening/closing door part installed on the flange part to open and close the opening, and having a door opening formed therethrough.

18. The substrate processing apparatus according to claim 17, wherein:
the heat exchange module is installed on the opening/closing door part by covering the door opening so as to communicate with the heating space through the door opening.

19. The substrate processing apparatus according to claim 17, further comprising:
a damper unit installed between the heater unit and the heat exchange module to communicate the heating space and the heat exchange module.

20. The substrate processing apparatus according to claim 19, wherein:
the heater unit comprises:
a side insulation part disposed to surround the inner tube;
a heating part provided on the inner surface of the side insulation part to generate heat according to applied power; and
an upper insulation part provided on the upper end of the side insulation part, having an exhaust flow path formed therein for discharging exhaust gas from the heating space, and coupled to the damper unit.

21. The substrate processing apparatus according to claim 15, wherein:
the heating space and the internal space are in communication with each other.

22. The substrate processing apparatus according to claim 15, wherein:
the inner tube comprises quartz; and the outer tube comprises SUS.

23. The substrate processing apparatus according to claim 15, wherein:
the internal space is maintained at a higher pressure than the processing space.

24. The substrate processing apparatus according to claim 15, wherein:
the heating space maintains a temperature of 800° C. or more during at least a portion of the process performed in the processing space.

25. The substrate processing apparatus according to claim 15, wherein:
the internal space maintains a pressure of 2 ATM or more during at least a portion of the process performed in the processing space.
